(19) United States
(12) Patent Application Publication
(10) Pub. No.: US 2008/0283854 A1
(43) Pub. Date: Nov. 20, 2008

(54) LIGHT EMITTING DIODE DEVICE LAYER STRUCTURE USING AN INDIUM GALLIUM NITRIDE CONTACT LAYER

(75) Inventors: Michael Iza, Santa Barbara, CA (US); Hirokuni Asamizu, Goleta, CA (US); Christian G. Van de Walle, Santa Barbara, CA (US); Steven P. DenBaars, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/113,745

(22) Filed: May 1, 2008

Related U.S. Application Data
(60) Provisional application No. 60/915,189, filed on May 1, 2007.

(51) Int. Cl. H01L 33/00

(52) U.S. Cl. 257/97; 438/47; 257/E33.032

(57) ABSTRACT

A light emitting diode device layer structure including a p-type contact layer that contains at least some indium (In), wherein the p-type contact layer is a not-intentionally doped strained nitride contact layer.

### CROSS-REFERENCE TO RELATED APPLICATIONS

This application claims the benefit under 35 U.S.C. Section 119(e) of co-pending and commonly-assigned U.S. Provisional Patent Application Ser. No. 60/915,189 filed on May 1, 2007, by Michael Iza, Hirokuni Asamizu, Christian G. Van de Walle, Steven P. DenBaars, and Shuji Nakamura, entitled “LIGHT EMITTING DIODE DEVICE LAYER STRUCTURE USING AN INDIUM GALLIUM NITRIDE CONTACT LAYER” attorneys' docket number 30794.227-US-P1 (2007-459-1), which application is incorporated by reference herein.

### BACKGROUND OF THE INVENTION

1. Field of the Invention

The present invention relates to an improved light emitting diode (LED) device layer structure including a p-type contact layer that contains at least some indium (In), wherein the p-type contact layer is a not-intentionally doped strained nitride contact layer.

2. Description of the Related Art

(Note: This application references a number of different publications as indicated throughout the specification by one or more reference numbers within brackets, e.g., [Ref(s). [x]. A list of these different publications ordered according to these reference numbers can be found below in the section entitled “References.” Each of these publications is incorporated by reference herein.)

The usefulness of gallium nitride (GaN) and its ternary and quaternary compounds, incorporating aluminum and indium (AlGaN, InGaN, AlInGaN), has been well established for fabrication of visible and ultraviolet optoelectronic devices and high-power electronic devices. These devices are typically grown epitaxially using growth techniques including molecular beam epitaxy (MBE), metalorganic chemical vapor deposition (MOCVD), and hydride vapor phase epitaxy (HVPE).

GaN and its alloys are most stable in the hexagonal wurtzite crystal structure, in which the structure is described by two (or three) equivalent basal plane axes that are rotated 120° with respect to each other (the a-axes), all of which are perpendicular to a unique c-axis. Group III and nitrogen atoms occupy alternating c-planes along the crystal's c-axis. The symmetry elements included in the wurtzite structure dictate that III-nitrides possess a bulk spontaneous polarization along this c-axis, and the wurtzite structure exhibits piezoelectric polarization.

The wurtzite lattice can be characterized by three parameters: the edge length of the basal hexagon (a), the height of the hexagon lattice cell (c), and the cation-anion bond length ratio (u) along the [0001] axis in units of c. Ideally the c/a ratio for the wurtzite crystal is 1.633 with a u value of 0.375. However, because of the different metal cation sizes and bond lengths, the c/a ratio for AlN, GaN, and InN will differ. GaN is the closest to the ideal crystal, followed by InN and AlN. The strong ionic behavior of the metal-nitrogen bond, and the lack of inversion symmetry, results in a strong polarization along the [0001] direction [Refs. 1-3].

In addition to the effects of the strong ionic bond of the crystal, the degree of non-ideality of the crystal lattice also affects the magnitude and direction of the polarization. Although the main contribution to the strength of polarization is attributed to the covalent bond parallel to the [0001] direction, the other three bonds are also equally ionic. These three bonds serve to counteract the polarization contributed by the other bond because they are pointed at angles opposite to the bond parallel to the c-axis. As the c/a ratio decreases (c decreases and a increases), the effect of the three angled bonds will decrease and the total polarization will increase, and vice versa. This total macroscopic polarization is thus referred to as spontaneous polarization (Pₛₚ) since it occurs in the equilibrium lattice at zero strain [Refs. 1-3].

From the previous discussion, it is not difficult to imagine that as the ideality of the crystal changes, it can strongly effect the actual polarization present in the crystal. One way of doing this is by adding strain to the crystal lattice, thereby changing the c/a ratio. This additional polarization present in strained III-Nitrides is referred to as piezoelectric polarization (Pₚₑ) [Refs. 1-3]. For example, if a thin layer of AlN is deposited onto Ga-face GaN (thus having AlN lattice matched to the underlying GaN film), the AlN layer will be put under tensile strain due to the smaller a parameter for AlN than that of GaN. Tensile strain in the AlN forces the c/a ratio to decrease, thereby increasing the piezoelectric polarization and thus increasing the total polarization in the AlN layer. However, since the a lattice parameter for InN is larger than that of GaN, a compressive strain in a thin InN layer grown lattice matched to Ga-face GaN will be observed. This will cause the piezoelectric polarization direction to point in the opposite direction to the spontaneous polarization direction, thereby decreasing the total polarization present in the InN layer.

FIGS. 1a-1d illustrate these effects for III-nitrides 100a, 100b, 100c, 100d grown pseudomorphically on both Ga-face and N-face GaN 102a, 102b, 102c, 102d, and show Pₛₚ and Pₚₑ directions in Ga-face AlₓGa₁₋ₓN 100a grown on Ga-face GaN 102a (FIG. 1a), N-face AlₓGa₁₋ₓN 100b grown on N-face GaN 102b (FIG. 1b), Ga-face InₓGa₁₋ₓN 100c grown on Ga-face GaN 102c (FIG. 1c), and N-face InₓGa₁₋ₓN 100d grown on N-face GaN 102d.

The AlGaN 100a is under tensile strain 104, the AlGaN 100b is under tensile strain 106, the InGaN 100c is under compressive strain 108 and the InGaN 100d is under compressive strain 110.

The AlGaN 100a is grown in the <0001> direction 112 on GaN 102a so that the last grown surface of the AlGaN 100a is Ga-face 114 (FIG. 1a), and the InGaN 100c is grown in the <0001> direction 116 on GaN 102c so that the last grown surface of the InGaN 100c is a Ga-face 118. The AlGaN 100b is grown in the <000-1> direction 120 on GaN 102b so that the last grown surface of the AlGaN 100b is N-face 122, and the InGaN 100d is grown in the <000-1> direction 124 on GaN 102d, so that the last grown surface of the InGaN 100d is an N-face 126.

Additionally, the external quantum efficiency or total efficiency (η_{L}) of LEDs can be defined by the following equation:

η_{L}=ηᵢₙₜηᵢₙⱼηₑₓₜ

where the extraction efficiency, ηₑₓₜ, is defined as the amount of photons extracted, the injection efficiency, ηᵢₙⱼ, is defined as the amount of carriers injected into the active region of the device, and the internal quantum efficiency, ηᵢₙₜ, is defined as the amount of photons generated in the active region of the device. The internal quantum efficiency of a device can be maximized by reducing the number of non-radiative centers, such as defects and impurities. The internal quantum and injection efficiencies of blue nitride based LEDs have already been improved to a high level by optimizing the deposition conditions of the device layers. Therefore, further improvement in external efficiency of a device would require improvement in the extraction efficiency and injection efficiency.

The injection efficiency of nitride based devices is hampered by the difficulty in obtaining an ohmic p-type contact with a low voltage drop across the metal-semiconductor interface. There are several methods to date that have been used in order to fabricate ohmic contacts to p-type III-nitride compounds, such as deposition of a Nickel/Gold (Ni/Au) contact, with subsequent oxidation at elevated temperatures, and the use of a transparent conducting oxide (TCO), such as Indium Tin Oxide (ITO). Another approach to improve the voltage drop across the metal/semiconductor interface is the use of a strained nitride contact layer grown on top of the nitride semiconductor device [Refs. 5-8]. The use of a strained nitride contact layer pseudomorphically grown atop the nitride device results in the tilting of the electric field in such a way that the tunneling of charge carriers through the barrier can be drastically enhanced [Ref. 8].

P-type doped strained contact layers have previously been demonstrated and have been shown to improve the performance of nitride devices [Refs. 8, 9]. However, p-type doping of nitride layers has been shown to drastically decrease the material quality by inducing crystal defects and gross morphological degradation of the nitride films [Ref. 10]. These effects were shown to have deleterious consequences on the electrical performance of the nitride films.

The present invention distinguishes itself from above mentioned methods by the use of a not-intentionally doped strained nitride contact layer in order to improve the total resistance of nitride based devices. This improved technique can be used as a means to reduce the resistance across the contact-to-semiconductor interface, thereby drastically reducing the operating voltage at a given current without the detrimental effects associated with doping of the nitride films. As a result, there is a need for improved methods for the growth of a not-intentionally doped nitride contact layer, wherein the film exhibits a reduced operating voltage at a given current. The present invention satisfies this need.

### BRIEF DESCRIPTION OF THE DRAWINGS

Referring now to the drawings in which like reference numbers represent corresponding parts throughout:

FIGS. 1a-1d are schematics illustrating spontaneous and piezoelectric polarization in pseudomorphically grown AlGaN/GaN and InGaN/GaN heterostructures for Ga-face and N-face films [Ref. 4].

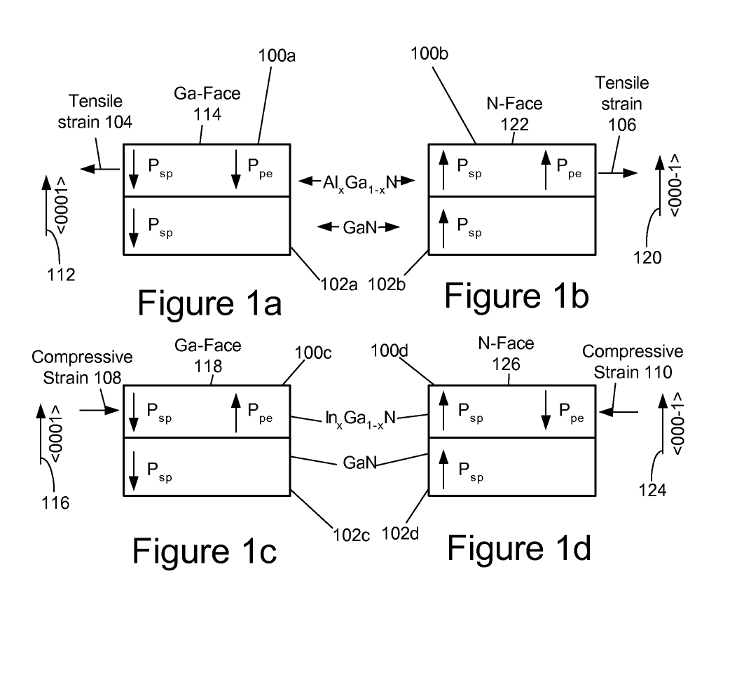

FIG. 2 is a flow chart of the preferred embodiment of the present invention.

FIG. 3 is a graph showing measured “on wafer” output power as a function of not-intentionally doped InGaN contact layer thickness.

FIG. 4 is a schematic showing a device layer structure for electrically contacting a nitride semiconductor device, according to the present invention.

### SUMMARY OF THE INVENTION

The present invention describes improved quality nitride devices using one or more not-intentionally doped strained contact layers. Not-intentionally doped strained nitride contact layers offer a means of improving the injection efficiency of III-nitride devices.

The term nitrides refers to any alloy composition of the (Ga,Al,In,B)N semiconductors having the formula GaₙAlₓIn_{y}B_{z}N where:

0≦n≦1, 0≦x≦1, 0≦y≦1, 0≦z≦1, and n+x+y+z=1

The not-intentionally doped strained contact layers may comprise multiple layers having varying or graded compositions, a heterostructure comprising one or more layers of dissimilar (Al,Ga,In,B)N composition, or one or more layers of dissimilar (Al,Ga,In,B)N composition. The not-intentionally doped strained contact layer or layers may be deposited using deposition techniques such as HVPE, MOCVD or MBE.

The not-intentionally doped strained contact layers may be deposited (for example, grown) in any crystallographic nitride direction, such as on a conventional c-plane oriented nitride semiconductor crystal, on a non-polar plane such as a-plane or m-plane, or on any semi-polar plane.

The present invention discloses a device layer structure for electrically contacting a nitride semiconductor device, comprising a p-type nitride layer of the nitride semiconductor device, an unintentionally doped (UID) strained nitride layer on the p-type nitride layer for forming a contact-to-semiconductor interface with a contact for the p-type nitride layer, wherein a resistance across the contact-to-semiconductor interface between the contact and the UID strained nitride layer is reduced as compared to a resistance across a contact-to-semiconductor interface formed directly between the contact and the p-type nitride layer. The UID strained nitride layer may interface both the p-type nitride layer and the contact. The UID strained nitride layer may be lattice mismatched to the p-type nitride layer.

The present invention further discloses a device layer structure comprising a p-type contact layer that is a semiconductor nitride layer containing at least some indium (In). The p-type contact layer may be a not-intentionally doped strained nitride contact layer. The nitride contact layer's thickness may be less than 10 nm. The nitride contact layer may be an indium gallium nitride (InGaN) contact layer. The nitride contact layer may be used in a device, such as a light emitting diode.

The present invention further discloses a method for fabricating a nitride semiconductor device with increased injection efficiency, comprising using an un-intentionally doped (UID) strained nitride layer on a p-type nitride layer of the semiconductor nitride device for forming a contact-to-semiconductor interface with a contact for the p-type nitride layer, so that a resistance across the contact-to-semiconductor interface between the contact and the UID strained nitride layer is reduced as compared to a resistance across a contact-to-semiconductor interface formed directly between the contact and the p-type nitride layer.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

Current nitride devices suffer from low injection efficiencies due to poor metal-to-semiconductor electrical characteristics. The present invention's use of not-intentionally doped nitride strained contact layers offers a means to improve the injection efficiency of nitride based devices by reducing the voltage drop across the metal-to-semiconductor interface without degradation of material quality introduced by doping of the contact layers. The present invention provides a means of enhancing (Ga,Al,In,B)N devices.

Technical Description

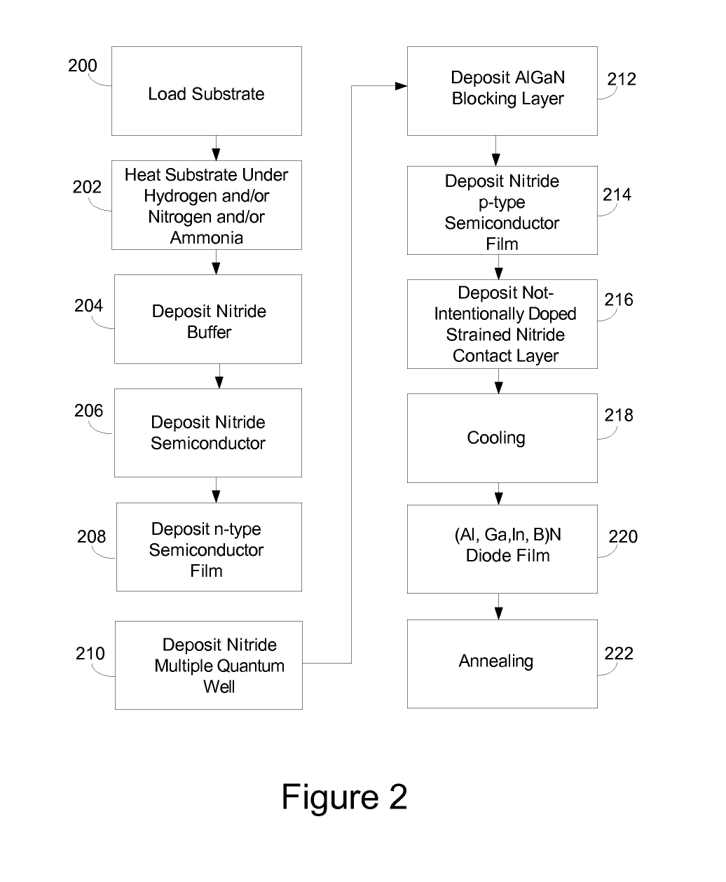

FIG. 2 is a flowchart that illustrates the steps of the MOCVD process for the growth not-intentionally doped strained InGaN contact layer, according to the preferred embodiment of the present invention that is described in the following paragraphs.

For the growth of not-intentionally doped strained contact layers; first, a sapphire (0001) substrate is loaded into an MOCVD reactor, as shown in Block 200. The reactor's heater is turned on and ramped to a set point temperature of 115° C. under hydrogen and/or nitrogen, as shown in Block 202. Generally, nitrogen and/or hydrogen flow over the substrate at atmospheric pressure in Block 202 (which is an optional step). After 20 minutes, the reactor's set point temperature is then decreased to 570° C. and 3 sccm of trimethylgallium (TMGa) is introduced into the reactor to initiate the GaN nucleation or buffer layer growth, as shown in Block 204. After 100 seconds, the GaN nucleation or buffer layer reaches the desired thickness. At this point, the TMGa flow is shut off and the reactor's temperature is increased to 1185° C.

Once the set point temperature is reached, 15 sccm of TMGa is introduced into the reactor to initiate the GaN growth for 15 minutes, as shown in Block 206. Once the desired GaN thickness is achieved, 4 sccm of Si₂H₆ is introduced into the reactor to initiate the growth of n-type GaN doped with silicon for 45 minutes, as shown in block 208.

Once the desired n-type GaN thickness is achieved, the reactor's temperature set point is decreased to 880° C., and 30 sccm of Triethylgallium (TEGa) is introduced into the reactor for 200 seconds to initiate the deposition of the GaN barrier, as shown in block 210. Once the desired barrier thickness is achieved, 70 sccm of Trimethylindium (TMIn) is introduced into the reactor for 24 seconds and then shut to initiate the deposition of the InGaN quantum wells, as shown in block 210. These two preceding steps are then repeated five times. After the last InGaN quantum well is deposited, 30 sccm of TEGa is introduced into the reactor for 160 seconds for growth of GaN and then shut; these preceding steps are referred to the LED's multiple quantum well (MQW), shown in block 210. Once the MQW is deposited, 1 sccm of TMGa and 1 sccm of Trimethylaluminum (TMAl) are introduced into the reactor for 100 seconds and then shut for the deposition of the AlGaN electron blocking layer, shown in block 212.

Once a desired thickness AlGaN thickness is achieved, the reactor's set point temperature is maintained at 880° C. and 3.5 sccm of TMGa and 50 sccm of Bis(cyclopentadienyl)magnesium (Cp₂Mg) is introduced into the reactor for 12 minutes and then shut for the deposition of p-type GaN doped with magnesium, as shown in block 214.

Once a desired p-type GaN thickness is achieved, the reactor set point temperature is increased to 930° C. and 40 sscm of TMIn along with 30 sccm of TEGa are introduced for 40 seconds for growth of the not-intentionally doped strained nitride contact layer, as shown in block 216.

Once a desired not-intentionally doped strained nitride contact layer thickness is achieved, the reactor is cooled down while flowing ammonia to preserve the GaN film, as shown in Block 218.

The end result is a nitride diode with a not-intentionally doped strained contact layer, as represented by Block 220.

Once the reactor has cooled, the nitride diode is removed and annealed in a hydrogen deficient atmosphere for 15 minutes at a temperature of 700° C. in order to activate the p-type GaN, as shown in Block 222.

Advantages and Improvements

Table 1 shows the voltage characteristics of an LED device structure using a not-intentionally doped strained nitride contact layer (in this case, an InGaN contact layer), known as sample B, compared to that of an LED device structure without an InGaN contact layer, known as sample A, for a drive current of 20 mA and 100 mA. The table also shows the measured “on wafer” output power for both devices.

TABLE 1

| Sample | Drive Current (mA) | Voltage (volts) | Output Power (mW) |
|---|---|---|---|
| A | 20 | 4.85 ± 0.0782 | 7.0 |
| B | 20 | 4.41 ± 0.0587 | 7.0 |
| A | 100 | 7.10 ± 0.268 | NA |
| B | 100 | 6.34 ± 0.085 | NA |

As can be seen, sample B has a drastically improved contact layer due to the lower operating voltage at both 20 mA and 100 mA. In addition, this improvement in operating voltage is achieved without a decrease in the measured output power of the device. Thus, the use of a not-intentionally doped, strained nitride contact layer, as described in the preferred embodiment of this invention, shows a dramatic enhancement in device operation by drastically reducing the operating voltage at both 20 mA and 100 mA drive currents in nitride based devices.

In addition, the InGaN contact layer thickness can be varied in order to study the effects of thickness on the contact layer properties. For example, the thickness of the contact layer may be varied by using 2 nm, 4 nm, and 6 nm thick contact layers.

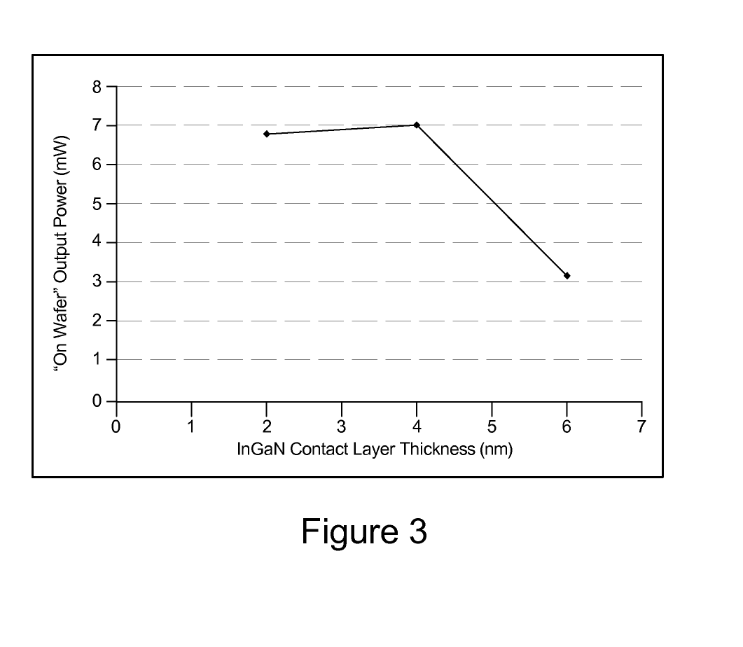

FIG. 3 shows the measured “on wafer” output power for the samples with various not-intentionally doped InGaN contact layer thicknesses. It is clear from the data that no degradation in output power is observed for samples with not-intentionally doped InGaN contact layer thicknesses of 2 nm and 4 nm. However, the output power dramatically decreases for the sample with 6 nm. This indicates that in order to achieve a reduction in forward voltage by using a not-intentionally doped InGaN contact layer, without compromising the device output power performance, the not-intentionally doped InGaN contact layer thickness should be less 10 nm.

Possible Modifications and Variations

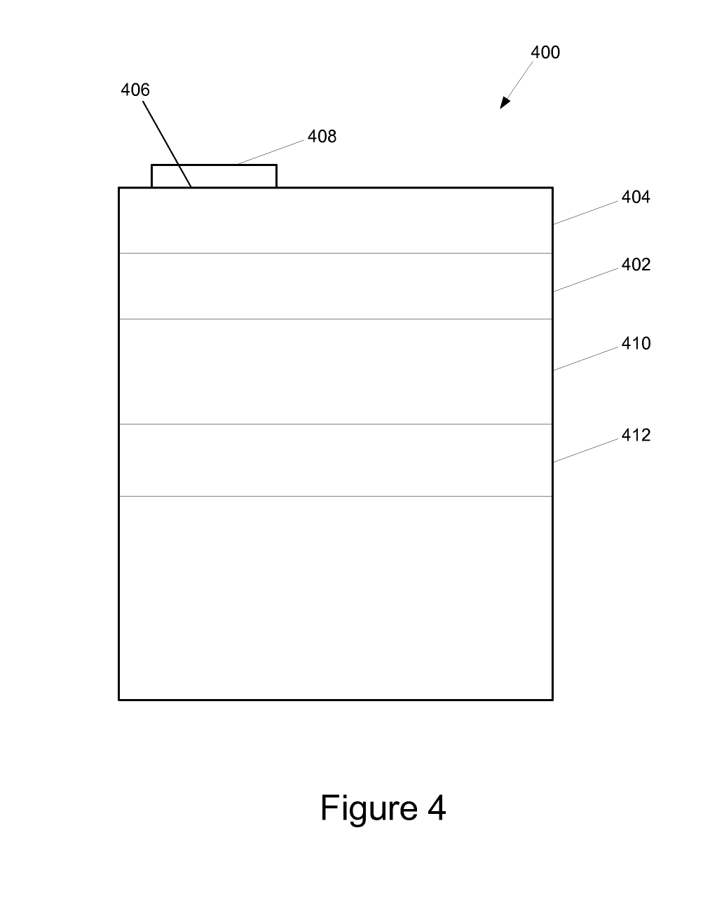

FIG. 4 is a schematic showing a device layer structure for electrically contacting a nitride semiconductor device 400, comprising a p-type nitride layer 402 of the nitride semiconductor device 400, an unintentionally doped (UID) strained nitride layer 404 on the p-type nitride layer 402 for forming a contact-to-semiconductor interface 406 with a contact 408 for the p-type nitride layer 402, wherein a resistance across the contact-to-semiconductor interface 406 between the contact 408 and the UID strained nitride layer 404 is reduced as compared to a resistance across a contact-to-semiconductor interface formed directly between the contact 408 and the p-type nitride layer 402. The UID strained nitride 404 layer may interface both the p-type nitride layer 402 and the contact 408 (i.e. there are no other layers between the UID layer 404 and the contact 408 or between the UID layer 404 and the p-type layer 402). In order to achieve strained conditions, the UID layer 404 is typically lattice mismatched to the p-type nitride layer 402. The device layer structure may comprise a p-type contact layer 404 that is a semiconductor nitride layer containing at least some indium.

The device layer structure is typically formed by growth, for example, by MOCVD, MBE, or HVPE (growth parameters may vary), but any method of fabrication that achieves the device layer structure having increased injection efficiency may be used (including, but not limited to non-growth methods such as wafer bonding).

For example, FIG. 2 shows a growth process for the growth of a not-intentionally doped strained nitride contact layer. The steps may comprise loading a substrate in a growth reactor (block 200), heating the substrate under hydrogen and/or nitrogen and/or ammonia (block 202), depositing a nitride buffer layer on the substrate (block 204), depositing a nitride semiconductor on the buffer layer (block 206), depositing an n-type nitride semiconductor film on the nitride semiconductor (block 208), depositing an active layer, such as a nitride MQW, on the n-type semiconductor film (block 210), depositing an AlGaN blocking layer on the active layer (block 212), depositing a nitride p-type semiconductor film on the blocking layer (block 214), depositing a not intentionally doped strained nitride contact layer on the p-type layer (block 216), cooling the structure (block 218), thereby achieving an (Al,Ga,In,B) N diode film (block 220) comprising the layers formed in blocks 202-216, and annealing the film (block 222). These steps are an example of one embodiment, and steps may be omitted or added as desired.

The UID layer 404 may be used to make contacts such as, but not limited to, ohmic contact and Schottky contact to the semiconductor device 400. The contact 408 is typically (but not exclusively) a metal alloy.

FIG. 4 also shows additional layers, such as an active region 410 between an n-type nitride layer 412 and the p-type nitride layer 402, wherein the device 400 is a light emitting diode. However, other devices that may benefit from improved injection efficiency and lower contact resistance, such as transistors or lasers, may also be fabricated.

III-nitride device layers may be grown in the <0001> or <000-1> direction, to achieve Ga-face, III-face, or N-face oriented devices.

Additional layers, other than UID layers, may be placed in between the p-type layer 402 and the UID layer 404, or between the UID layer 404 and the contact 408. Throughout this disclosure, “not intentionally doped” is equivalent to a UID layer.

### References

The following references are incorporated by reference herein:
11. W. Q. Chen and S. K. Hark, J. Appl. Phys. 77, 5747 (1995).
2. A. Bykhovski, B. L. Gelmont, and M. S. Shur, J. Appl. Phys. 81, 6332 (1997).
3. O. Ambacher, J. Smart, J. R. Shealy, N. G. Weimann, K. Chu, M. Murphy, W. J. Schaff, L. F. Eastman, R. Dimitrov, L. Wittmer, M. Stutzmann, W. Rieger, and J. Hilsenbeck, J. Appl. Phys. 85, 3222 (1999).
4. O. Ambacher, B. Foutz, J. Smart, J. R. Shealy, N. G. Weimann, K. Chu, M. Murphy, A. J. Sierakowski, W. J. Schaff, and L. F. Eastman, J. Appl. Phys. 87, 334 (1999).
5. L. Li, E. F. Schubert, and J. W. Graff, Appl. Phys. Lett. 76, 2728 (2000).
6. T. Gessmann, Y.-L. Li, E. L. Waldron, J. W. Graff, J. K. Sheu, and E. F., Schubert, Appl. Phys. Lett. 80, 982 (2002).
7. K. Kumakura, T. Makimoto, and N. Kobayashi, Appl. Phys. Lett. 79, 2588 (2001).
8. Th. Gessmann, J. W. Graff, Y.-L. Li, E. L. Waldron, and E. F. Schubert, J. Appl. Phys. 92, 3740 (2002).
9. K. Kumakura, T. Makimoto, and N. Kobayashi, Jpn. J. Appl. Phys. Vol. 42 (2003) pp. 2254-2256, Part 1, No. 4B, (2003).
10. P. Kozodoy, H. Xing, S. P. DenBaars, U. K. Mishra, A. Saxler, R. Perrin, S. Elhamri, and W. C. Mitchel, J. Appl. Phys. 87, 1832 (2000).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A device layer structure for electrically contacting a nitride semiconductor device, comprising:
a p-type nitride layer of the nitride semiconductor device;
an unintentionally doped (UID) strained nitride layer on the p-type nitride layer for forming a contact-to-semiconductor interface with a contact for the p-type nitride layer, wherein a resistance across the contact-to-semiconductor interface between the contact and the UID strained nitride layer is reduced as compared to a resistance across a contact-to-semiconductor interface formed directly between the contact and the p-type nitride layer.

2. The device layer structure of claim 1, wherein the UID strained nitride layer interfaces both the p-type nitride layer and the contact.

3. The device layer structure of claim 1, wherein the UID strained nitride layer is lattice mismatched to the p-type nitride layer.

4. A device layer structure comprising a p-type contact layer that is a semiconductor nitride layer containing at least some indium (In).

5. The device layer structure of claim 4, wherein the p-type contact layer is a not-intentionally doped strained nitride contact layer.

6. The device layer structure of claim 5, wherein the nitride contact layer's thickness is less than 10 nm.

7. The device layer structure of claim 5, wherein the nitride contact layer comprises multiple layers having varying or graded compositions.

8. The device layer structure of claim 5, wherein the nitride contact layer is grown on a non-polar, c-plane, or semi-polar plane.

9. The device layer structure of claim 5, wherein the nitride contact layer is an indium gallium nitride (InGaN) contact layer.

10. The device layer structure of claim 4, wherein the device is a light emitting diode.

11. A method for fabricating a nitride semiconductor device with increased injection efficiency, comprising:
(a) using an un-intentionally doped (UID) strained nitride layer on a p-type nitride layer of the semiconductor nitride device for forming a contact-to-semiconductor interface with a contact for the p-type nitride layer, so that a resistance across the contact-to-semiconductor interface between the contact and the UID strained nitride layer is reduced as compared to a resistance across a contact-to-semiconductor interface formed directly between the contact and the p-type nitride layer.

12. The method of claim 11, wherein the UID strained nitride layer interfaces both the p-type nitride layer and the contact.

13. The method of claim 11, wherein the UID strained nitride layer is lattice mismatched to the p-type nitride layer.

14. The method of claim 11, wherein the UID strained nitride layer is indium gallium nitride (InGaN).

15. The method of claim 11, wherein the UID strained nitride layer is grown on the p-type nitride layer.
